(19) United States
(12) Patent Application Publication
(10) Pub. No.: US 2025/0210477 A1
(43) Pub. Date: Jun. 26, 2025

(54) SEMICONDUCTOR PACKAGING STRUCTURE

(71) Applicant: QUANZHOU SANAN INTEGRATED CIRCUIT CO., LTD., Quanzhou City (CN)

(72) Inventors: Kai CHEN, Quanzhou City (CN); Jianming YU, Quanzhou City (CN); Yan LI, Quanzhou City (CN); Liang ZHOU, Quanzhou City (CN); Anping YUAN, Quanzhou City (CN); Huiqiang GAO, Quanzhou City (CN)

(21) Appl. No.: 18/901,505

(22) Filed: Sep. 30, 2024

(30) Foreign Application Priority Data
Dec. 22, 2023 (CN) 202311787179.5

(51) Int. Cl. H01L 23/495; H01L 23/31; H01L 23/373

(52) U.S. Cl. CPC H01L 23/49568; H01L 23/3114; H01L 23/3737; H01L 23/49555

(57) ABSTRACT

A semiconductor packaging structure includes a lead frame, a first thermally conductive layer, a second thermally conductive layer, a chip, and an encapsulation body. The first thermally conductive layer is disposed on a surface of the lead frame, and includes a plurality of first silver powder particles. The second thermally conductive layer is disposed on the first thermally conductive layer, and includes a resin and a plurality of second silver powder particles. The first silver powder particles are smaller in size than the second silver powder particles. The chip is disposed on the second thermally conductive layer. A bottom surface of the chip and a portion of a side surface of the chip contact the second thermally conductive layer. The encapsulation body covers the lead frame, the first thermally conductive layer, the second thermally conductive layer, and the chip.

### CROSS-REFERENCE TO RELATED APPLICATION

This application claims priority to Chinese Invention Patent Application No. CN202311787179.5, filed on Dec. 22, 2023, the entire disclosure of which is incorporated by reference herein.

### FIELD

The disclosure relates to integrated circuit packaging, and more particularly to a semiconductor packaging structure.

### BACKGROUND

A conventional semiconductor packaging structure generally includes a lead frame, a die bond adhesive, a chip, and an encapsulation body. The chip is bonded to the lead frame by the die bond adhesive. The encapsulation body covers the lead frame, the die bond adhesive, and the chip. The conventional semiconductor packaging structure often experiences delamination, which often occurs at a side surface of the chip (e.g., an area between the side surface of the chip and the encapsulation body), a top surface of the chip (e.g., an area between the top surface of the chip and the encapsulation body), and a bottom surface of the chip (e.g., an area between the lead frame and the die bond adhesive). Delamination occurs even more often in high power products, resulting in deterioration or even failure in product performance.

Therefore, delamination needs to be resolved so as to prevent chip packaging products from failure due to delamination.

### SUMMARY

Therefore, an object of the disclosure is to provide a semiconductor packaging structure that can alleviate at least one of the drawbacks of the prior art.

According to the disclosure, the semiconductor packaging structure includes a lead frame, a first thermally conductive layer, a second thermally conductive layer, a chip, and an encapsulation body.

The first thermally conductive layer is disposed on a surface of the lead frame, and includes a plurality of first silver powder particles.

The second thermally conductive layer is disposed on the first thermally conductive layer, and includes a resin and a plurality of second silver powder particles. The first silver powder particles are smaller in size than the second silver powder particles.

The chip is disposed on the second thermally conductive layer. A bottom surface of the chip and a portion of a side surface of the chip contact the second thermally conductive layer.

The encapsulation body covers the lead frame, the first thermally conductive layer, the second thermally conductive layer, and the chip.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a first embodiment of a semiconductor packaging structure according to the disclosure.

FIG. 2 is an enlarged schematic view of region A in FIG. 1.

FIG. 3 is a schematic view illustrating dimensions of various layers of the semiconductor packaging structure shown in FIG. 1.

FIG. 4 is a schematic view illustrating dimensions of various layers of the semiconductor packaging structure shown in FIG. 2.

FIG. 5 is a schematic view illustrating a second embodiment of the semiconductor packaging structure according to the disclosure.

FIG. 6 is a schematic diagram illustrating a semiconductor packaging structure prepared in Comparative Example 1.

FIG. 7 is a schematic diagram illustrating a semiconductor packaging structure prepared in Comparative Example 2.

FIG. 8 is a C-scan imaging of first semiconductor packaging structures prepared using Example 1.

FIG. 9 is a T-scan imaging of the first semiconductor packaging structures prepared using Example 1.

FIG. 10 is a slice image illustrating a first semiconductor packaging structure prepared using Example 1.

FIG. 11 is a slide image illustrating a second semiconductor packaging structure prepared using Example 1.

FIG. 12 is a slice image illustrating a region of a third semiconductor packaging structure prepared using Comparative Example 1.

FIG. 13 is a slice image illustrating another region of the third semiconductor packaging structure prepared using Comparative Example 1.

FIG. 14 is a slice image illustrating a region of a fourth semiconductor packaging structure prepared using Comparative Example 1.

FIG. 15 is a slice image illustrating another region of the fourth semiconductor packaging structure prepared using Comparative Example 1.

FIG. 16 is a slice image illustrating a region of a fifth semiconductor packaging structure prepared using Comparative Example 1.

FIG. 17 is a slice image illustrating another region of the fifth semiconductor packaging structure prepared using Comparative Example 1.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

When a conventional semiconductor packaging structure is subjected to injection molding, or experiences temperature change in the external environment or heat generated by a chip during operation, internal stress is produced among an encapsulation body, the chip, and a lead frame of the conventional semiconductor packaging structure. The internal stress may lead to delamination within the conventional semiconductor packaging structure, thereby reducing the lifespan of the conventional semiconductor packaging structure or causing complete failure of the conventional semiconductor packaging structure. To resolve the issue of delamination within the conventional semiconductor packaging structure, the following disclosure is provided.

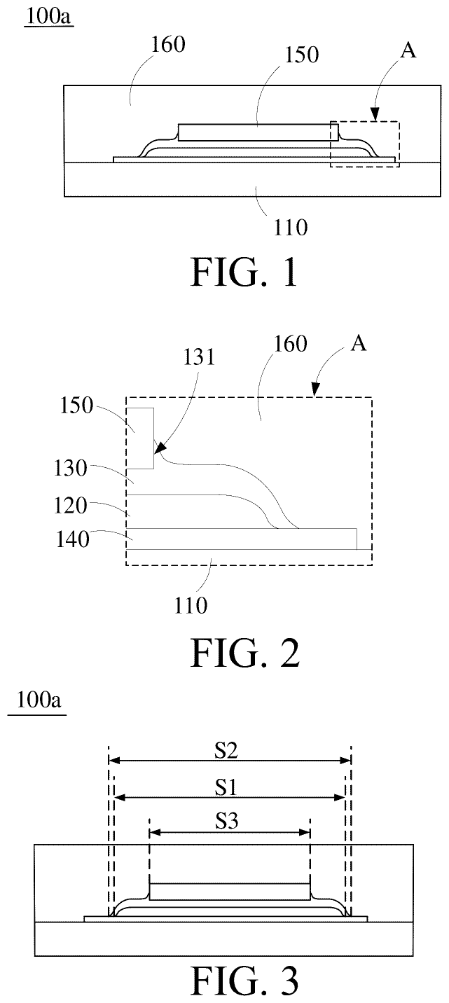

Referring to FIGS. 1 and 2, a semiconductor packaging structure 100a, which is a first embodiment of a semiconductor packaging structure according to the disclosure, includes a lead frame 110, a first thermally conductive layer 120, a second thermally conductive layer 130, a chip 150, and an encapsulation body 160.

The first thermally conductive layer 120 is disposed on a surface of the lead frame 110, and includes a plurality of first silver powder particles. The second thermally conductive layer 130 is disposed on the first thermally conductive layer 120, and includes a resin and a plurality of second silver powder particles. The first silver powder particles are smaller in size than the second silver powder particles. The chip 150 is disposed on the second thermally conductive layer 130, and a bottom surface of the chip 150 and a portion of a side surface of the chip 150 contact the second thermally conductive layer 130. The encapsulation body 160 covers the lead frame 110, the first thermally conductive layer 120, the second thermally conductive layer 130, and the chip 150.

Because of the first silver powder particles are smaller in size than the second silver powder particles, a density of the first thermally conductive layer 120 is greater than a density of the second thermally conductive layer 130. Therefore, the first thermally conductive layer 120 has a good flexural strength to counter a deformation stress of the lead frame 110, thereby reducing or avoiding delamination underneath the chip 150. The second thermally conductive layer 130 includes the resin, which may reduce a partial frontal stress induced in the chip 150 in a thickness direction or a top-bottom direction, thereby reducing delamination at a top of the chip 150 due to the frontal stress. In addition, compared to the first thermally conductive layer 120, a thermal expansion coefficient of the second thermally conductive layer 130 which includes the resin is closer to a thermal expansion coefficient of the encapsulation body 160, which results in better adhesion of the second thermally conductive layer 130 to the encapsulation body 160. By virtue of the portion of the side surface of the chip 150 being connected to the encapsulation body 160 via the second thermally conductive layer 130, delamination at the side surface of the chip 150 is avoided. As such, by virtue of the first thermally conductive layer 120 cooperating with the second thermally conductive layer 130, delamination within entire structure of the semiconductor packaging structure 100a may be reduced or avoided.

Furthermore, to improve an ability of the second thermally conductive layer 130 to reduce the frontal stress of the chip 150 in the thickness direction, a percentage amount of the first silver powder particles in the first thermally conductive layer 120 is greater than a percentage amount of the second silver powder particles in the second thermally conductive layer 130. For example, the first thermally conductive layer 120 is formed from a fully sinterable silver adhesive, and the first silver powder particles are present in an amount no smaller than 95 wt % based on 100 wt % of the first thermally conductive layer 120. The fully sinterable silver adhesive does not include any resin. In some embodiments, the density of the first thermally conductive layer 120 is greater than the density of the second thermally conductive layer 130.

In certain embodiments, to improve the ability of the second thermally conductive layer 130 to reduce the frontal stress of the chip 150 in the thickness direction, the percentage amount of the second silver powder particles in the second thermally conductive layer 130 is smaller than the percentage amount of the first silver powder particles, thereby allowing a proportion of the resin in the second thermally conductive layer 130 to be greater, so as to improve the ability of the second thermally conductive layer 130 to reduce the frontal stress of the chip 150 in the thickness direction. In some embodiments, the second thermally conductive layer 130 is formed from a semi-sinterable silver adhesive, and the second silver powder particles are present in an amount ranging from 85 wt % to 98 wt % based on 100 wt % of the second thermally conductive layer 130.

In some embodiments, to make the density of the first thermally conductive layer 120 greater, a size of the first silver powder particles may be smaller. For example, a diameter of the first silver powder particles is smaller than 1 μm.

In some embodiments, to reduce the frontal stress of the chip 150 in the thickness direction, a diameter of the second silver powder particles is greater than or equal to 1 μm. Specifically, the diameter of the second silver powder particles ranges from 2 μm to 20 μm (e.g., 2 μm, 5 μm, 8 μm, 15 μm, 20 μm). By virtue of the diameter of the second silver powder particles is greater than or equal to 1 μm, there are more spaces between the second silver powder particles for disposal of the resin, thereby improving the ability of the second thermally conductive layer 130 to reduce the frontal stress of the chip 150 in the thickness direction. More specifically, the diameter of the second silver powder particles may range from 8 μm to 12 μm (e.g., 8 μm, 9 μm, 10 μm, 12 μm).

In some embodiments, referring to FIG. 1 in combination with FIG. 2, the second thermally conductive layer 130 covers an edge of the first thermally conductive layer 120. In other embodiments, the second thermally conductive layer 130 does not cover the edge of the first thermally conductive layer 120. That is to say, the second thermally conductive layer 130 exposes the edge of the first thermally conductive layer 120.

More specifically, referring to FIG. 2 in combination with FIG. 1, the semiconductor packaging structure further includes an electroplated silver layer 140 that is disposed between the first thermally conductive layer 120 and the lead frame 110.

The abovementioned configuration delivers effects in two aspects. First, by virtue of the electroplated silver layer 140 contacting an area of the lead frame 110 where the chip 150 is disposed, the area of the lead frame 110 under the chip 150 may be prevented from oxidation. Second, an adhesion between the fully sinterable silver adhesive and the electroplated silver layer 140 is better than an adhesion between the fully sinterable silver adhesive and the lead frame 110, therefore by virtue of bonding the fully sinterable silver adhesive to the lead frame 110 via the electroplated silver layer 140, a bonding strength between the first thermally conductive layer 120 and the lead frame 110 is improved.

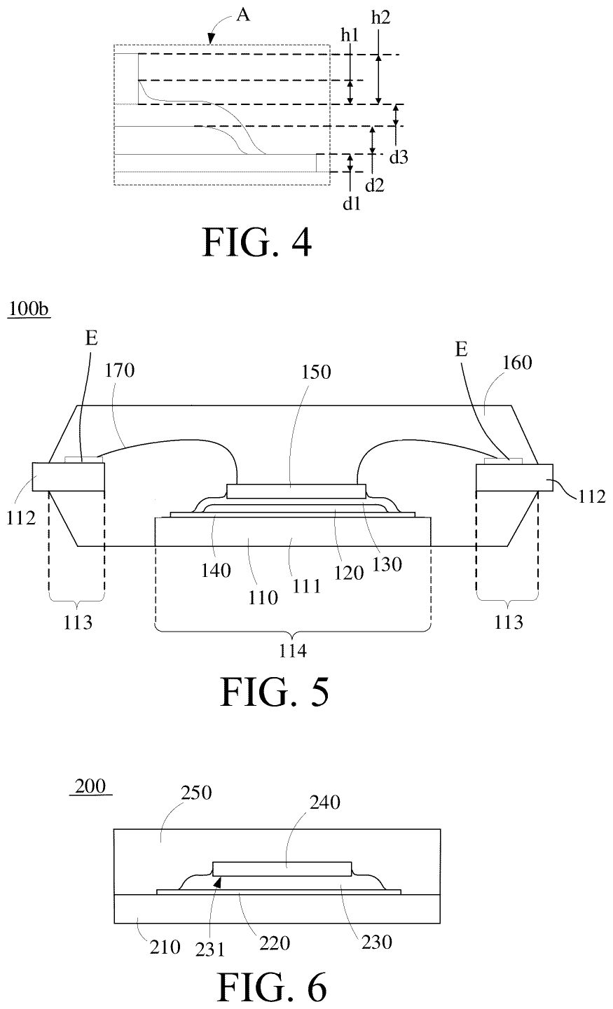

In some embodiments, referring to FIG. 4 in combination with FIGS. 1 and 2, a thickness (d1) of the electroplated silver layer 140 ranges from 1.78 μm to 7.62 μm (e.g., 1.78 μm, 2 μm, 4.56 μm, 7.62 μm).

In certain embodiments, the semi-sinterable silver adhesive is made from a material including the resin, a volatilizable material, and the second silver powder particles. During a sintering process, the volatilizable material is evaporated, thereby forming the second thermally conductive layer 130 that includes the resin and the second silver powder particles.

Compared to a thermal expansion coefficient of the fully sinterable silver adhesive, a thermal expansion coefficient of the semi-sinterable silver adhesive is closer to that of the encapsulation body 160 due to including the resin. In this way, during a process of forming the second thermally conductive layer 130 that includes the resin and the second silver powder particles from the semi-sinterable silver adhesive that includes the resin, the volatilizable material, and the second silver powder particles, thermal stress delamination of the second thermally conductive layer 130 from the encapsulation body 160 due to their different thermal expansion coefficients may be reduced or eliminated. The resin may be, but not limited to, epoxy resin.

In some embodiments, when the percentage amount of the second silver powder particles in the second thermally conductive layer 130 is greater than 80%, a thermal conductivity of the second thermally conductive layer 130 is greater than or equal to 100 W/mK. Based on 100 wt % of the semi-sinterable silver adhesive, the resin, the volatilizable material, and the second silver powder particles are present in an amount ranging from 5 wt % to 12 wt % (e.g., 5 wt %, 10 wt %, 12 wt %), 5 wt % to 10 wt % (e.g., 5 wt %, 7 wt %, 10 wt %), and 80 wt % to 95 wt % (e.g., 80 wt %, 90 wt %, 95 wt %), respectively. In such way, the thermal conductivity of the second thermally conductive layer 130 may be greater than or equal to 100 W/mK.

For example, the fully sinterable silver adhesive includes the first silver powder particles, 2-ethyl-1, and 3-hexanediol. The first silver powder particles are present in an amount ranging from 85 wt % to 95 wt % based on 100 wt % of the fully sinterable silver adhesive. In some embodiments, the weight percents of the first silver powder particles, 2-ethyl-1, and 3-hexanediol in the fully sinterable silver adhesive may be referred to the weight percents of corresponding components of a commercially available product with Model No. MAX102 (manufacturer: Nihon Handa Co. Ltd.). That is to say, the fully sinterable silver adhesive may be a product of the MAX102 series, but is not limited thereto.

Referring to FIG. 3 in combination with FIGS. 1 and 2, the first thermally conductive layer 120 has a first area (S₁), the second thermally conductive layer 130 has a second area (S₂), and the chip 150 has a third area (S₃). The first area (S₁), the second area (S₂), and the third area (S₃) satisfy the following formulas:

S₁/S₃≥1.2

S₂/S₃>1.

By virtue of the abovementioned method, the semiconductor packaging structure 100a may have sufficient thermal conductivity and bonding strength.

In some embodiments, the second thermally conductive layer 130 is formed with a chip groove 131. The chip groove 131 has a bottom wall and a side wall. The chip 150 is embedded in the chip groove 131. The bottom wall of the chip groove 131 contacts the bottom surface of the chip 150, and the side wall of the chip groove 131 contacts the side surface of the chip 150. In such way, by virtue of the chip 150 being embedded in the chip groove 131, delamination at a top surface and the side surface of the chip 150 may be prevented or avoided.

In some embodiments, referring to FIG. 4 in combination with FIGS. 1 and 2, a thickness (d2) of the first thermally conductive layer 120 ranges from 20 μm to 200 μm (e.g., 20 μm, 110 μm, 200 μm). It should be noted that, when the thickness of the first thermally conductive layer 120 is smaller than 20 μm, delamination is more likely to occur within the semiconductor packaging structure 100a due to deformation stress from the lead frame 110. If the thickness (d2) of the first thermally conductive layer 120 is greater than 200 μm, manufacturing cost may increase significantly, and the delamination is also more likely to occur within the semiconductor packaging structure 100a due to the frontal stress in the top-bottom direction. In certain embodiments, the thickness (d2) of the first thermally conductive layer 120 ranges from 20 μm to 100 μm (e.g., 20 μm, 50 μm, 60 μm, 100 μm).

In some embodiments, a thickness (d3) of a portion of the second thermally conductive layer 130 underneath the chip groove 131 ranges from 15 μm to 185 μm (e.g., 15 μm, 100 μm, 185 μm).

By virtue of the thickness (d2) of the first thermally conductive layer 120 cooperating with the thickness (d3) of the portion of the second thermally conductive layer 130 underneath the chip groove 131, the delamination within the semiconductor packaging structure 100a may be reduced, even when the chip 150 therein has a large length-to-width ratio. The chip 150 has a length and a width that are perpendicular to each other, and each of the length and the width of the chip 150 is perpendicular to the thickness direction. The length of the chip 150 has a first dimension, and the width of the chip 150 has a second dimension. The large length-to-width ratio means a ratio of the first dimension to the second dimension, which ranges from 2:1 to 10:1 (e.g., 2:1, 5:1, 10:1). Specifically, the ratio of the first dimension to the second dimension may range from 5.5:1 to 7.5:1 (e.g., 5.5:1, 6:1, 7.5:1). More specifically, the ratio of the first dimension to the second dimension may be 6.4:1.

In some embodiments, referring to FIG. 2 in combination with FIG. 1, a height (h1) of the side wall of the chip groove 131 is smaller than a height (h2) of the chip 150. The height (h1) of the side wall of the chip groove 131 is 20% to 90% (e.g., 20%, 55%, 90%) of the height (h2) of the chip 150. In this way, delamination underneath the chip 150 and at the side surface of the chip 150 may be avoided.

Referring to FIG. 5 in combination with FIGS. 1 and 2, a second embodiment of the semiconductor packaging structure is denoted by 100b and is similar to the semiconductor packaging structure 100a, and the similarities therebetween will not be repeated herein. The differences therebetween reside in the following.

In the second embodiment, the lead frame 110 includes a base island 111 and a plurality of conductive pins 112. The conductive pins 112 are disposed around a periphery of the base island 111 in a spaced apart manner. The first thermally conductive layer 120 is disposed on the base island 111. The chip 150 has the top surface, at least one electrode that is disposed on the top surface, and at least one conductive wire 170 that electrically connects the at least one electrode to one of the conductive pins 112. The encapsulation body 160 covers the base island 111, the at least one conductive wire 170, and a portion of each of the conductive pins 112. In this embodiment, the at least one electrode includes multiple electrodes denoted by (E) in FIG. 5. In some embodiments, the electroplated silver layer 140 is formed between the first thermally conductive layer 120 and the base island 111.

Furthermore, referring to FIG. 5, each of the conductive pins 12 has a first region 113 that is being covered by the encapsulation body 160. The base island 111 has a second region 114 that is distal from the chip 150 and that is exposed from the encapsulation body 160. By virtue of the second region 114 that is exposed from the encapsulation body 160, efficiency of heat dissipation of the base island 111 may be improved.

Referring to FIGS. 1 and 2, a method for manufacturing the semiconductor packaging structure 100a is provided and includes the following steps.

In step S110, the lead frame 110 is provided.

In step S120, the first thermally conductive layer 120, the second thermally conductive layer 130, the chip 150, and the encapsulation body 160 are sequentially formed on the lead frame 110 in a direction away from the lead frame 110.

The second thermally conductive layer 130 is formed with the chip groove 131. The bottom wall of the chip groove 131 contacts the bottom surface of the chip 150, and the side wall of the chip groove 131 contacts the side surface of the chip 150. The encapsulation body 160 covers the lead frame 110, the first thermally conductive layer 120, the second thermally conductive layer 130, and the chip 150. The first thermally conductive layer 120 is formed from the fully sinterable silver adhesive, and the second thermally conductive layer 130 is formed from the semi-sinterable silver adhesive.

Exemplarily, but not limitedly, the semi-sinterable silver adhesive may be applied to the fully sinterable silver adhesive when the fully sinterable silver adhesive is in a wet state or a dry state, and the chip 150 is disposed on the semi-sinterable silver adhesive when the semi-sinterable silver adhesive is in the wet state.

In an example, the fully sinterable silver adhesive is applied with a thickness ranging from 30 μm to 210 μm (e.g., 30 μm, 60 μm, 110 μm, 210 μm) so as to form into the first thermally conductive layer 120 having a thickness that ranges from 20 μm to 200 μm (e.g., 20 μm, 50 μm, 100 μm, 200 μm) after sintering, and the semi-sinterable silver adhesive is applied with a thickness ranging from 30 μm to 205 μm (e.g. as 30 μm, 70 μm, 120 μm, 205 μm) so as to form into the second thermally conductive layer 130 after sintering. The thickness (d3) of the portion of the second thermally conductive layer 130 underneath the chip groove 131 ranges from 15 μm to 185 μm (e.g., 15 μm, 50 μm, 100 μm, 185 μm).

Exemplarily, but not limitedly, the fully sinterable silver adhesive has a shrinkage of approximately 10 μm after sintering, and the semi-sinterable silver adhesive has a shrinkage of approximately 15 μm to 20 μm (e.g., 15 μm, 17 μm, μm) after sintering.

In some embodiments, to take adhesive aging control and production capacity (units per hour, UPH) into consideration, a double head dispensing hot melt glue dispenser is used for applying the fully sinterable silver adhesive and the semi-sinterable silver adhesive.

Exemplarily, but not limitedly, the chip 150 may include at least SiC (silicon carbide) materials or GaN (gallium carbide) materials. For example, the chip 150 may include GaN-on-SiC (gallium carbide on silicon carbide) materials. In such way, the chip 150 including the SiC and GaN materials has advantages including high voltage resistance, high thermal conductivity, and low power consumption, and is adapted to be used in 5G base stations and new energy industries.

The semiconductor packaging structure 100a of the present disclosure is further described below.

### Example 1

Referring to FIGS. 1 and 2, a method of manufacturing the semiconductor package structure 100a includes the following steps of S11 to S16.

In step S11, each of the lead frame 110 and the chip 150 is provided, and the electroplated silver layer 140 is disposed on the lead frame 110.

The area of the lead frame 110 is greater than an area of the chip 150. The length of the chip 150 has the first dimension, and the width of the chip 150 has the second dimension. The ratio of the first dimension to the second dimension is 6.4:1.

In step S12, the fully sinterable silver adhesive is disposed on the electroplated silver layer 140, so as to form a first coating layer.

Specifically, a thickness of the first coating layer ranges from 30 30 μm to 210 μm, and the fully sinterable silver adhesive is a product with Model No. MAX102.

In step S13, the semi-sinterable silver adhesive is disposed on the first coating layer, so as to form a second coating layer.

The semi-sinterable silver adhesive includes the resin, the volatilizable material, and the second silver powder particles. Based on 100 wt % of the semi-sinterable silver adhesive, the resin, the volatilizable material, and the second silver powder particles are present in an amount ranging from 5 wt % to 12 wt % (e.g., 5 wt %, 10 wt %, 12 wt %), 5 wt % to 10 wt % (e.g., 5 wt %, 7 wt %, 10 wt %), and 80 wt % to 95 wt % (e.g., 80 wt %, 90 wt %, 95 wt %), respectively. A thickness of the second coating layer ranges from 30 μm to 205 μm.

The semi-sinterable silver adhesive may be applied to the first coating layer while the first coating layer formed from the fully sinterable silver adhesive is in the wet state or the dry state. The wet state refers to a state in which the fully sinterable silver adhesive has not been fully sintered and cured and thus remains wet. The dry state refers to a state in which the fully sinterable silver adhesive is sintered and cured and thus is dried.

In step S14, the chip 150 is disposed on the semi-sinterable silver adhesive while the second coating layer formed from the semi-sinterable silver adhesive is in the wet state, and the second coating layer is formed with the chip groove 131 covering at least a portion of the thickness of the chip 150.

To form the chip groove 131, the chip 150 is disposed on the second coating layer while the semi-sinterable silver adhesive is in the wet state. The chip 150 is pressed against the second coating layer, thereby forming the chip groove 131 in the second coating layer.

In step S15, the first coating layer and the second coating layer are sintered to form the first thermally conductive layer 120 and the second thermally conductive layer 130, respectively.

After sintering, the first coating layer shrinks to form the first thermally conductive layer 120 having a thickness that ranges from 20 μm to 200 μm, and the second coating layer shrinks to form the second thermally conductive layer 130. The thickness (d3) of the portion of the second thermally conductive layer 130 underneath the chip groove 131 ranges from 15 μm to 185 μm (e.g., 15 μm, 100 μm, 185 μm).

In step S16, the encapsulation body 160 is formed on the chip 150, and covers the lead frame 110, the electroplated silver layer 140, the first thermally conductive layer 120, the second thermally conductive layer 130, and the chip 150, thereby producing the semiconductor packaging structure 100a of Example 1.

### Comparative Example 1

Referring to FIG. 6 in combination with FIGS. 1 and 2, a main difference between a semiconductor packaging structure 200 of Comparative Example 1 and the semiconductor packaging structure 100a of Example 1 resides in that the semiconductor packaging structure 200 of Comparative Example 1 is not provided with the second thermally conductive layer 130. A method of manufacturing the semiconductor packaging structure 200 of Comparative Example 1 includes the following steps of S21 to S25.

In step S21, each of a lead frame 210 and a chip 240 is provided, and an electroplated silver layer 220 is disposed on the lead frame 210.

An area of the lead frame 210 is greater than an area of the chip 240. A length of the chip 240 has a first dimension, and a width of the chip 240 has a second dimension. A ratio of the first dimension to the second dimension is 6.4:1.

In step S22, a fully sinterable silver adhesive is disposed on the electroplated silver layer 220 to form a first coating layer.

Specifically, a thickness of the first coating layer ranges from 30 μm to 210 μm, and the fully sinterable silver adhesive is a product with model number MAX102.

In step S23, the chip 240 is disposed on the fully sinterable silver adhesive when the first coating layer formed from the fully sinterable silver adhesive is in a wet state, and the first coating layer is formed with a chip groove 231 covering at least a portion of a thickness of the chip 240.

In step S24, the first coating layer is sintered to form a first thermally conductive layer 230.

Wherein, after sintering, the first coating layer shrinks to form the first thermally conductive layer 230 having a thickness that ranges from 20 μm to 200 μm.

In step S25, an encapsulation body 250 is formed on the chip 240, and covers the lead frame 210, the electroplated silver layer 220, the first thermally conductive layer 230, and the chip 240, thereby producing the semiconductor packaging structure 200 of Comparative Example 1.

### Comparative Example 2

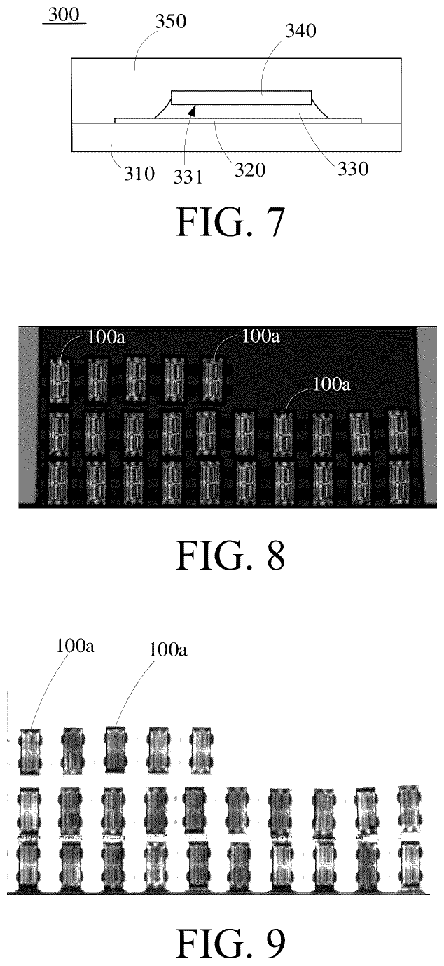

Referring to FIG. 7 in combination with FIGS. 1 and 2, a main difference between a semiconductor packaging structure 300 of Comparative Example 2 and the semiconductor packaging structure 100a of Example 1 resides in that the semiconductor packaging structure 300 of Comparative Example 2 is not provided with the first thermally conductive layer 120. A method of manufacturing the semiconductor packaging structure 200 of Comparative Example 2 includes the following steps of S31 to S35.

In step S31, each of a lead frame 310 and a chip 340 is provided, and an electroplated silver layer 320 is disposed on the lead frame 310.

An area of the lead frame 310 is greater than an area of the chip 340. A length of the chip 340 has a first dimension, and a width of the chip 340 has a second dimension. A ratio of the first dimension to the second dimension is 6.4:1.

In step S32, a semi-sinterable silver adhesive is disposed on the electroplated silver layer 320 to form a second coating layer.

The semi-sinterable silver adhesive includes the resin, the volatilizable material, and the second silver powder particles. Based on 100 wt % of the semi-sinterable silver adhesive, the resin, the volatilizable material, and the second silver powder particles are present in an amount ranging from 5 wt % to 12 wt % (e.g., 5 wt %, 10 wt %, 12 wt %), 5 wt % to 10 wt % (e.g., 5 wt %, 7 wt %, 10 wt %), and 80 wt % to 95 wt % (e.g., 80 wt %, 90 wt %, 95 wt %), respectively. A thickness of the second coating layer ranges from 30 μm to 205 μm.

In step S33, the chip 340 is disposed on the semi-sinterable silver adhesive when the second coating layer formed from the semi-sinterable silver adhesive is in a wet state, and the second coating layer is formed with a chip groove 331 covering at least a portion of a thickness of the chip 340.

In step S34, the second coating layer is sintered to form a second thermally conductive layer 330.

After sintering, the second coating layer shrinks to form the second thermally conductive layer 330, and a thickness of a portion of the second thermally conductive layer 330 underneath the chip groove 331 ranges from 15 μm to 185 μm.

In step S35, an encapsulation body 350 is formed on the chip 340, and covers the lead frame 310, the electroplated silver layer 320, the second thermally conductive layer 330, and the chip 340, thereby producing the semiconductor packaging structure 300 of Comparative Example 2.

The semiconductor packaging structure of each of Example 1, Comparative Example 1, and Comparative Example 2 was subjected to a temperature cycling test for 500 hours. In each cycle of the temperature cycling test, the semiconductor packaging structures 100a, 200, 300 were held in a temperature of 150° C. for a period of 15 minutes, then cooled down to −65° C. within a next period of 15 minutes, and thereafter kept at −65° C. for another period of 15 minutes, followed by being heated up to 150° C. from −65° C. so as to complete one cycle.

### Test 1

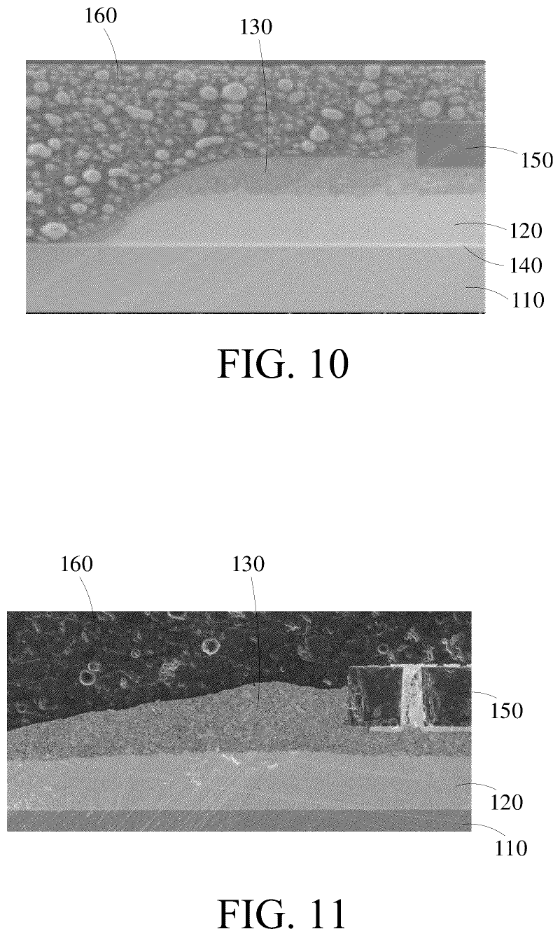

The semiconductor packaging structure 100a of Example 1 was used to prepare a first semiconductor packaging structure. The first semiconductor packaging structure, after being subjected to the temperature cycling test for 500 hours, was subjected to C-scanning, T-scanning, and slicing, the results of which are shown in FIG. 8, FIG. 9, and FIG. 10, respectively.

Referring to FIGS. 8 to 10 in combination with FIGS. 1 and 2, no significant delamination was found between the side surface of the chip 150 and a sidewall of the second thermally conductive layer 130 contacting the chip groove 131, the top surface of the chip 150, and an area underneath the chip 150.

### Test 2

The semiconductor packaging structure 100a of Example 1 was used to prepare a second semiconductor packaging structure. The first semiconductor packaging structure and the second semiconductor packaging structure are substantially the same except that the second thermally conductive layer 130 exposes the edge of the first thermally conductive layer 120 in Test 2. The second semiconductor packaging structure was subjected to slicing and the results of which is shown in FIG. 11.

Referring to FIG. 11 in combination with FIGS. 1 and 2, no significant delamination was found between the side surface of the chip 150 and the sidewall of the second thermally conductive layer 130 contacting the chip groove 131, the top surface of the chip 150, and the area underneath the chip 150.

### Test 3

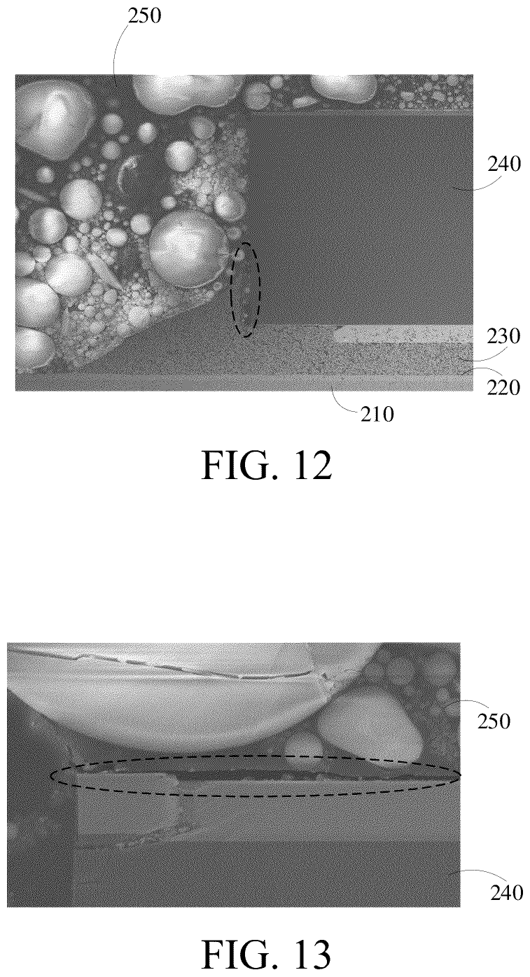

The semiconductor packaging structure 200 of Comparative Example 1 was used to prepare a third semiconductor packaging structure. Of the third semiconductor packaging structure, a thickness of a portion of the first thermally conductive layer 230 underneath the chip groove 231 is 30 μm. The third semiconductor packaging structure was subjected to slicing and the results of which is shown in FIGS. 12 and 13.

Referring to FIG. 12 in combination with FIG. 6, in the third semiconductor packaging structure, significant delamination was found between a side surface of the chip 240 and a sidewall of the first thermally conductive layer 230 contacting the chip groove 231, as shown in the area within the dotted circle in FIG. 12. Referring to FIG. 13 in combination with FIG. 6, significant delamination was found between a top surface of the chip 240 and the encapsulation body 250, as shown in the area within the dotted circle in FIG. 13.

### Test 4

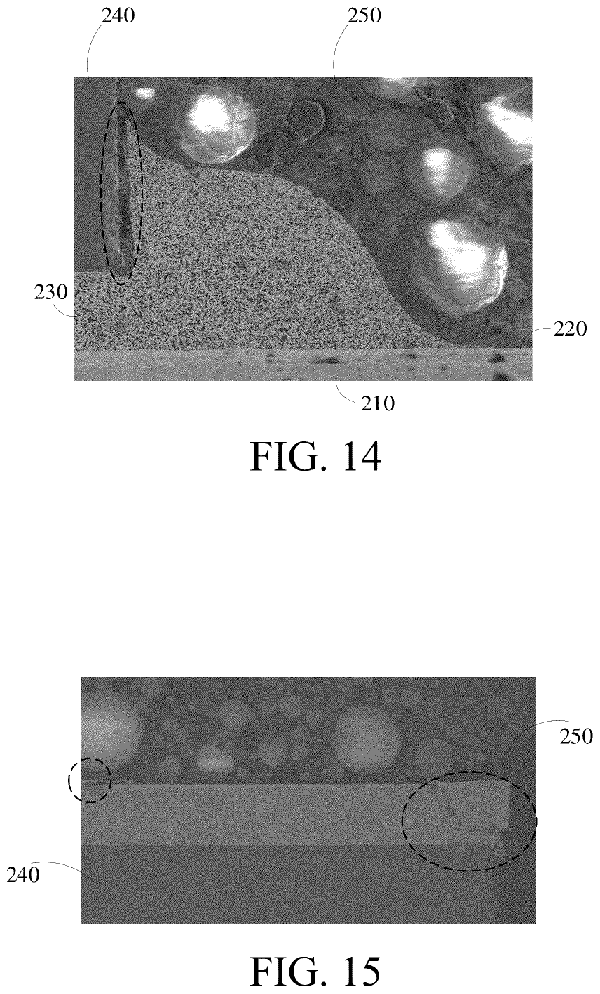

The semiconductor packaging structure 200 of Comparative Example 1 was used to prepare a fourth semiconductor packaging structure. Of the fourth semiconductor packaging structure, the thickness of the portion of the first thermally conductive layer 230 underneath the chip groove 231 is 50 μm. The fourth semiconductor packaging structure was subjected to slicing and the results of which are shown in FIGS. 14 and 15.

Referring to FIG. 14 in combination with FIG. 6, in the fourth semiconductor packaging structure, significant delamination was found between the side surface of the chip 240 and the sidewall of the first thermally conductive layer 230 contacting the chip groove 231, as shown in the area within the dotted circle in FIG. 14. Referring to FIG. 15 in combination with FIG. 6, significant delamination was found between the top surface of the chip 240 and the encapsulation body 250, as shown in the areas within the dotted circles in FIG. 15.

### Test 5

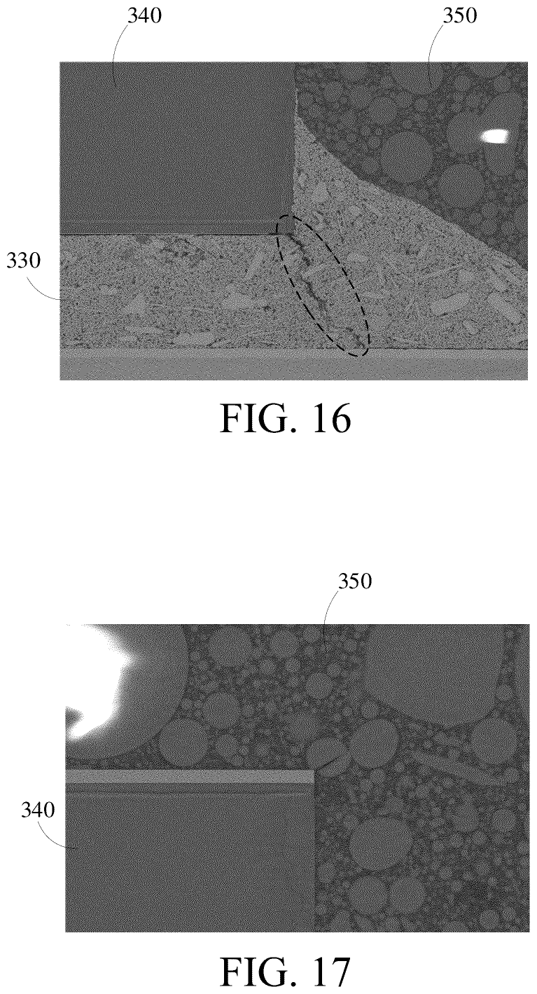

The semiconductor packaging structure 300 of Comparative Example 2 was used to prepare a fifth semiconductor packaging structure. Of the fifth semiconductor packaging structure, the thickness of the portion of the second thermally conductive layer 330 underneath the chip groove 331 is 50 μm. The fifth semiconductor packaging structure was subjected to slicing and the results of which are shown in FIGS. 16 and 17.

Referring to FIG. 16 in combination with FIG. 7, in the fifth semiconductor packaging structure, no delamination was found between a side surface of the chip 340 and a sidewall of the second thermally conductive layer 330 contacting the chip groove 331. However, significant delamination was found in the second thermally conductive layer 330 underneath the chip 340, as shown in the dotted circle area in FIG. 16. Referring to FIG. 17 in combination with FIG. 7, no delamination was found between a top surface of the chip 340 and the encapsulation body 350.

In summary, as can be seen from the results of Test 3 and Test 4, the delamination between the side surface of the chip 240 and the sidewall of the first thermally conductive layer 230 contacting the chip groove 231 is not resolved by merely increasing the thickness of the first thermally conductive layer 230. As can be seen from the results of Test 5, the delamination in the second thermally conductive layer 330 is not resolved by having the second thermally conductive layer 330. Comparing the results of Test 3 and Test 5 with the results of Test 1, and Test 2, it can be seen that by virtue of the first thermally conductive layer 120 and the second thermally conductive layer 130 cooperating with the chip groove 131 in each of Test 1 and Test 2, the delamination between the side surface of the chip 240 and the sidewall of the first thermally conductive layer 230 contacting the chip groove 231 as in Test 3 and Test 4 may be resolved, and the delamination in the second thermally conductive layer 330 as in Test 5 is also resolved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor packaging structure, comprising:
a lead frame;
a first thermally conductive layer disposed on a surface of said lead frame, and including a plurality of first silver powder particles;
a second thermally conductive layer disposed on said first thermally conductive layer, and including a resin and a plurality of second silver powder particles, said first silver powder particles being smaller in size than said second silver powder particles;
a chip disposed on said second thermally conductive layer, a bottom surface of said chip and a portion of a side surface of said chip contacting said second thermally conductive layer; and
an encapsulation body covering said lead frame, said first thermally conductive layer, said second thermally conductive layer, and said chip.

2. The semiconductor packaging structure as claimed in claim 1, wherein said first thermally conductive layer is formed from a fully sinterable silver adhesive, and said first silver powder particles is present in an amount no smaller than 95 wt % based on 100 wt % of said first thermally conductive layer.

3. The semiconductor packaging structure as claimed in claim 1, wherein a percentage amount of said second silver powder particles in said second thermally conductive layer is smaller than a percentage amount of said first silver powder particles in said first thermally conductive layer.

4. The semiconductor packaging structure as claimed in claim 1, wherein a diameter of said first silver powder particles is smaller than 1 μm, and a diameter of said second silver powder particles is greater than or equal to 1 μm.

5. The semiconductor packaging structure as claimed in claim 1, wherein a diameter of said second silver powder particles ranges from 2 μm to 20 μm.

6. The semiconductor packaging structure as claimed in claim 1, wherein said second thermally conductive layer is formed from a semi-sinterable silver adhesive, said second silver powder particles being present in an amount ranging from 85 wt % to 98 wt % based on 100 wt % of said second thermally conductive layer.

7. The semiconductor packaging structure as claimed in claim 1, wherein a thickness of said first thermally conductive layer ranges from 20 μm to 200 μm.

8. The semiconductor packaging structure as claimed in claim 1, wherein said lead frame includes a base island and a plurality of conductive pins, said conductive pins being disposed around a periphery of said base island in a spaced apart manner, said first thermally conductive layer being disposed on said base island, said chip having a top surface, at least one electrode that is disposed on said top surface, and at least one conductive wire that electrically connects said at least one electrode to one of said conductive pins, said encapsulation body covering said base island, said at least one conductive wire, and a portion of each of said conductive pins.

9. The semiconductor packaging structure as claimed in claim 8, wherein each of said conductive pins has a first region that is being covered by said encapsulation body, said base island having a second region that is distal from said chip and that is exposed from said encapsulation body.

10. The semiconductor packaging structure as claimed in claim 1, further comprising an electroplated silver layer that is disposed between said first thermally conductive layer and said lead frame.

11. The semiconductor packaging structure as claimed in claim 10, wherein a thickness of said electroplated silver layer ranges from 1.78 μm to 7.62 μm.

12. The semiconductor packaging structure as claimed in claim 1, wherein a thermal conductivity of said chip is greater than or equal to 100 W/mK.

13. The semiconductor packaging structure as claimed in claim 1, wherein said first thermally conductive layer has a first area (S₁), said second thermally conductive layer has a second area (S₂), and said chip has a third area (S₃), said first area (S₁), said second area (S₂), and said third area (S₃) satisfying the following formulas:
S₁/S₃≥1.2
S₂/S₃>1.

14. The semiconductor packaging structure as claimed in claim 1, wherein said second thermally conductive layer is formed with a chip groove, said chip groove having a bottom wall and a side wall, said chip being embedded in said chip groove, said bottom wall of said chip groove contacting said bottom surface of said chip, said side wall of said chip groove contacting said side surface of said chip.

15. The semiconductor packaging structure as claimed in claim 14, wherein a thickness of a portion of said second thermally conductive layer underneath said chip groove ranges from 15 μm to 185 μm.

16. The semiconductor packaging structure as claimed in claim 14, wherein a height of said side wall of said chip groove is smaller than a height of said chip.

17. The semiconductor packaging structure as claimed in claim 14, wherein a height of said side wall of said chip groove is 20% to 90% of a height of said chip.

18. The semiconductor packaging structure as claimed in claim 1, wherein said chip has a length and a width that are perpendicular to each other, said length of said chip having a first dimension, said width of said chip having a second dimension, a ratio of said first dimension to said second dimension ranging from 2:1 to 10:1.

19. The semiconductor packaging structure as claimed in claim 18, wherein a ratio of said first dimension to said second dimension ranging from 5.5:1 to 7.5:1.

20. The semiconductor packaging structure as claimed in claim 1, wherein said second thermally conductive layer covers or exposes an edge of said first thermally conductive layer.
